(19) United States
(12) Patent Application Publication
(10) Pub. No.: US 2026/0081101 A1
(43) Pub. Date: Mar. 19, 2026

(54) ELECTRON MICROSCOPE SAMPLE INSERTION AND REMOVAL TOOL

(71) Applicant: Battelle Memorial Institute, Richland, WA (US)

(72) Inventors: Alexander Smith, Richland, WA (US); Adam G. Ryan, Richland, WA (US); Mark G. Wirth, Richland, WA (US); Daniel E. Perea, Richland, WA (US); Annalisa McKinney, Richland, WA (US)

(21) Appl. No.: 19/330,469

(22) Filed: Sep. 16, 2025

Related U.S. Application Data
(60) Provisional application No. 63/695,159, filed on Sep. 16, 2024.

(51) Int. Cl. H01J 37/20

(52) U.S. Cl. CPC H01J 37/20; H01J 2237/2007; H01J 2237/20285

(57) ABSTRACT

An end effector device for use with a scanning electron microscope includes a body defining a shaft extending along a longitudinal axis between a distal end and a proximal end. The proximal end features a bulbous portion, while the distal end has a first aperture aligned with the longitudinal axis, designed to receive a stem of a scanning electron microscope sample holder. The proximal end has a second aperture aligned with the longitudinal axis to receive an extension rod. The body also has a clip aperture, defined as a blind bore extending partially into the shaft, substantially orthogonal to the longitudinal axis. A clip is positioned within the clip aperture, held in place with a pin traversing through a pin aperture, allowing the clip to transition between a stem-engaging and a release configuration. A spring is positioned between the clip and the body to bias the clip to the stem-engaging configuration. The body is 3D printed, starting at the planar proximal end defined by the bulbous portion.

### CROSS-REFERENCE TO RELATED APPLICATION(S)

This application claims the benefit of priority to U.S. Provisional Application No. 63/695,159, filed Sep. 16, 2024, which application is incorporated herein by reference in its entirety.

### STATEMENT OF GOVERNMENT INTEREST

This invention was made with government support under Contract DE-AC05-76RL01830 awarded by the U.S. Department of Energy. The government has certain rights in the invention.

### TECHNICAL FIELD

The present invention relates generally to the field of scanning electron microscopy and more particularly to the design and manufacture of end effectors for handling and transferring sample holders.

### BACKGROUND

In the field of scanning electron microscopy (SEM) and related technologies, precise handling and transfer of samples is important for accurate experimentation and analysis. Samples are typically mounted on specialized sample holders positioned within a Specimen Shuttle Suitcase Device (SSSD) for loading in a SEM for observation. Traditional sample holders, often referred to as “pucks,” were originally designed for use in Atom Probe Topography (APT) machines but have since been re-purposed for use in other analytical systems. These pucks, along with their handling devices, are now commonly employed across multiple types of instruments for securely holding and transferring samples.

End effectors are designed to securely transfer sample holders into and out of a sample stage, ensuring the sample holder is firmly held to prevent misalignment or damage. However, traditional end effectors have several limitations, including loose grasping of sample holders and difficulty in replacement due to their stainless steel construction. Advancements like laser sintering 3D printing have produced newer models, but these often have undesirable material properties, such as brittleness and poor fit, leading to breakage and rubbing against interior walls of the analytical instruments.

Additionally, the compatibility of end effectors with different analytical instrument brands remains problematic. While some end effectors work with specific systems like those from CAMECA, they may not be effective with machines from other manufacturers, such as Quorum Technologies. This lack of interoperability limits their utility in diverse laboratory settings where multiple types of SEMs are used.

### SUMMARY

Embodiments of the present disclosure pertain to an end effector configured to be 3D printed using an extrusion printer, thereby facilitating the use of a variety of materials. This configuration enhances the replaceability and accessibility of the end effector and allows it to be tailored for specific environmental applications, such as possessing desirable thermal conductivity and performance characteristics in a vacuum.

In some embodiments, the distal end of the end effector can be shaped to closely follow the profile of the sample holder, thereby ensuring that the holder remains stable and rigidly aligned with the end effector, which mitigates the risk of instability during transfer. Additionally, the end effectors described herein can feature thicker walls and added reinforcement relative to conventional end effectors, thereby inhibiting the tip from breaking off during use. Moreover, embodiments of the present disclosure may incorporate a trimmed-down structure designed to minimize inadvertent contact or rubbing against the inside walls of a SSSD, enabling compatibility with machines and devices from a variety of manufacturers.

One aspect of the present disclosure provides an end effector device for use with a scanning electron microscope, including a body defining a shaft extending along a longitudinal axis between a distal end and a proximal end, the proximal end including a bulbous portion, the distal end defining a first aperture aligned with the longitudinal axis and configured to receive a stem of a scanning electron microscope sample holder, and the proximal end defining a second aperture aligned with the longitudinal axis and configured to receive an end of an extension rod, wherein the body further defines a clip aperture defined as a blind bore extending partially into the shaft between the distal end and the proximal end substantially orthogonal to the longitudinal axis, a clip positioned within the clip aperture and held in position with a pin traversing through a pin aperture extending through the body, enabling the clip to transition between a stem engaging configuration and a release configuration, a spring positioned between the clip and the body to bias the clip to the stem engaging configuration, wherein the body is 3D printed through a 3D printing process, and wherein the bulbous portion defines a planar proximal end of the body configured to serve as a starting point for the 3D printing process.

In one embodiment, the 3D printing process can progress in layers between the planar proximal end and the distal end.

In one embodiment, the body can be constructed of polyphenylsulfone (PPSU).

Another embodiment of the present disclosure provides an end effector device for use with a scanning electron microscope, including a body defining a shaft extending along a longitudinal axis between a distal end and a proximal end, the proximal end including a bulbous portion, the distal end defining a first aperture aligned with the longitudinal axis and configured to receive a stem of a scanning electron microscope sample holder, and the proximal end defining a second aperture aligned with the longitudinal axis and configured to receive an end of an extension rod, wherein the body further defines a clip aperture defined as a blind bore extending partially into the shaft between the distal end and the proximal end substantially orthogonal to the longitudinal axis, a clip positioned within the clip aperture and held in position with a pin traversing through a pin aperture extending through the body, enabling the clip to transition between a stem engaging configuration and a release configuration, a spring positioned between the clip and the body to bias the clip to the stem engaging configuration, and wherein the first aperture defines an inner chamfer including a surface configured to extend over at least 50% of a corresponding chamfered surface of the stem of the scanning electron microscope sample holder.

Yet another embodiment of the present disclosure provides an end effector device for use with a scanning electron microscope, including a body defining a shaft extending along a longitudinal axis between a distal end and a proximal end, the proximal end including a bulbous portion, the distal end defining a first aperture aligned with the longitudinal axis and configured to receive a stem of a scanning electron microscope sample holder, and the proximal end defining a second aperture aligned with the longitudinal axis and configured to receive an end of an extension rod, wherein the body further defines a clip aperture defined as a blind bore extending partially into the shaft between the distal end and the proximal end substantially orthogonal to the longitudinal axis, a clip positioned within the clip aperture and held in position with a pin traversing through a pin aperture extending through the body, enabling the clip to transition between a stem engaging configuration and a release configuration, a spring positioned between the clip and the body to bias the clip to the stem engaging configuration, wherein the clip defines a latch grip and the body further defines a latch grip aperture oriented substantially parallel to the clip aperture, enabling the latch grip to grip the stem of the scanning electron microscope sample holder positioned within the first aperture, wherein the latch grip aperture is positioned at a distance of at least 1 mm from the distal end.

In one embodiment, the latch grip aperture can include at least one of filleted or chamfered corners positioned along an exterior surface of the body.

In one embodiment, the clip can further define a latch effector presenting a manipulation surface featuring at least one of filleted or chamfered corners, enabling compatibility of the end effector device with a variety of scanning electron microscope sample stage configurations.

A variety of additional inventive aspects will be set forth in the description that follows. The inventive aspects can relate to individual features and to combinations of features. It is to be understood that both the forgoing general description and the following detailed description are exemplary and explanatory only and are not restrictive of the broad inventive concepts upon which the embodiments disclosed herein are based.

### BRIEF DESCRIPTION OF THE DRAWINGS

The accompanying drawings, which are incorporated in and constitute a part of the description, illustrate several aspects of the present disclosure. A brief description of the drawings is as follows:

FIG. 1 is a profile view depicting an end effector device operably coupling a microscope sample holder with an extension rod, in accordance with an embodiment of the disclosure.

FIG. 2 is a cross-sectional view depicting the end effector device of FIG. 1.

FIG. 3 is a close-up, cross-sectional view depicting the end effector device of FIG. 2 in a stem engaging configuration.

FIG. 4 is a close-up, cross-sectional view depicting the end effector device of FIG. 2 in a release configuration.

FIG. 5 is a perspective view of a microscope sample holder including a flag configured to engage with a sample stage to secure the microscope sample holder in position.

FIG. 6 is an end view depicting the microscope sample holder of FIG. 5 with the flag in the locked configuration.

FIG. 7 is an end view depicting the microscope sample holder of FIG. 5 with the flag in the unlocked configuration.

FIG. 8 is a perspective view depicting the microscope sample holder of FIG. 5 positioned within a sample stage.

FIG. 9 is a perspective view of an end effector device approaching a microscope sample holder positioned within a sample stage.

FIG. 10 is a cross-sectional view depicting the end effector device of FIG. 9 coupling to a stem of the microscope sample holder.

FIG. 11 is a perspective view depicting rotation of the end effector device of FIG. 9 relative to the microscope sample holder.

FIG. 12 is a perspective view depicting withdrawal of the end effector device and microscope sample holder.

FIG. 14 is a perspective view depicting an end effector device and microscope sample holder position within a SSSD, in accordance with an embodiment of the disclosure.

FIG. 14 is a cross-sectional view depicting an interaction between an end effector device and a SSSD, and accordance with an embodiment of the disclosure.

FIG. 15 is a cross-sectional view depicting release of the end effector device of FIG. 12 from the microscope sample holder.

FIG. 16 is a close-up, cross-sectional view depicting the end effector device of FIG. 13.

FIG. 17 is a cross-sectional view depicting a flag-only end effector device.

FIG. 18 is a cross-sectional view depicting an end effector device in accordance with an embodiment of the present disclosure.

FIG. 19 is a top plan view depicting an end effector device, in accordance with an embodiment of the disclosure.

FIG. 20 is a profile view depicting the end effector device of FIG. 16.

FIG. 21 is a cross-sectional view depicting the end effector device of FIG. 16.

FIG. 22 is a proximal end view depicting the end effector device of FIG. 16.

FIG. 23 is a cross-sectional view depicting the end effector device of FIG. 16.

FIG. 24 is a perspective view depicting the end effector device of FIG. 16.

FIG. 25 is a profile view depicting an end effector device operably coupling a microscope sample holder with an extension rod, in accordance with an alternative embodiment of the disclosure.

FIG. 26 is a cross-sectional view depicting the end effector device of FIG. 22.

FIG. 27 is a close-up, cross-sectional view depicting the end effector device of FIG. 22 in a stem engaging configuration.

### DETAILED DESCRIPTION

Reference will now be made in detail to exemplary aspects of the present disclosure that are illustrated in the accompanying drawings. Wherever possible, the same reference numbers will be used throughout the drawings to refer to the same or like parts.

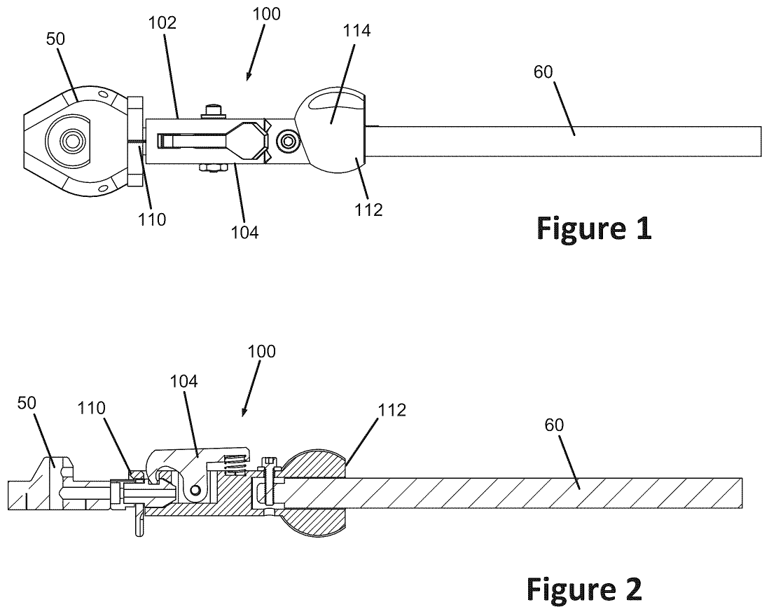

Referring to FIGS. 1-4, an end effector device 100 is depicted in accordance with an embodiment of the disclosure. Other embodiments, such as those depicted in FIGS. 22-24, are also contemplated. The purpose of the end effector device 100 can be to facilitate the loading and unloading of specimens into analytical devices capable of interfacing with an SSSD. As depicted, the end effector device 100 can include a body 102, a clip 104, and a spring 106.

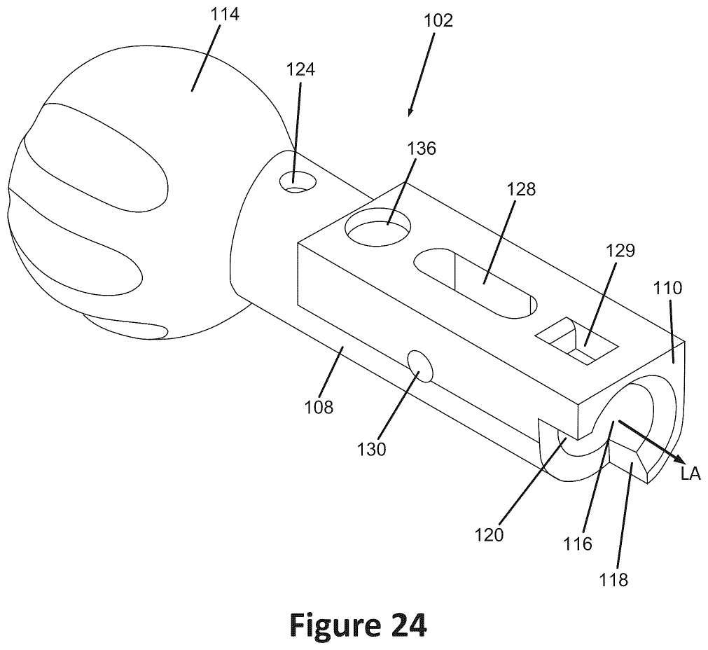

In embodiments, the body 102 (also depicted in FIG. 24) can be defined by a shaft 108 extending along a longitudinal axis (LA) between a distal end 110 and a proximal end 112. A bulbous portion 114, generally having a knob-like or partially spherical shape, can be formed in proximity to the proximal end 112, such that the shaft 108 and the bulbous portion 114 form a unitary, single-piece component extending between the distal end 110 and the proximal end 112.

The distal end 110 of the body 102 can define a first aperture 116, generally aligned with the longitudinal axis and shaped and sized to receive a stem 52 of a scanning electron microscope sample holder 50. In some embodiments, the first aperture 116 can be a substantially cylindrical bore, with its axis generally aligned with the longitudinal axis of the body 102. Further, in some embodiments, the distal end 110 can define one or more surfaces 118, 120 configured to engage with a flag 54 defined by the microscope sample holder 50 as the end effector device 100 can be rotated either clockwise or counterclockwise about the longitudinal axis.

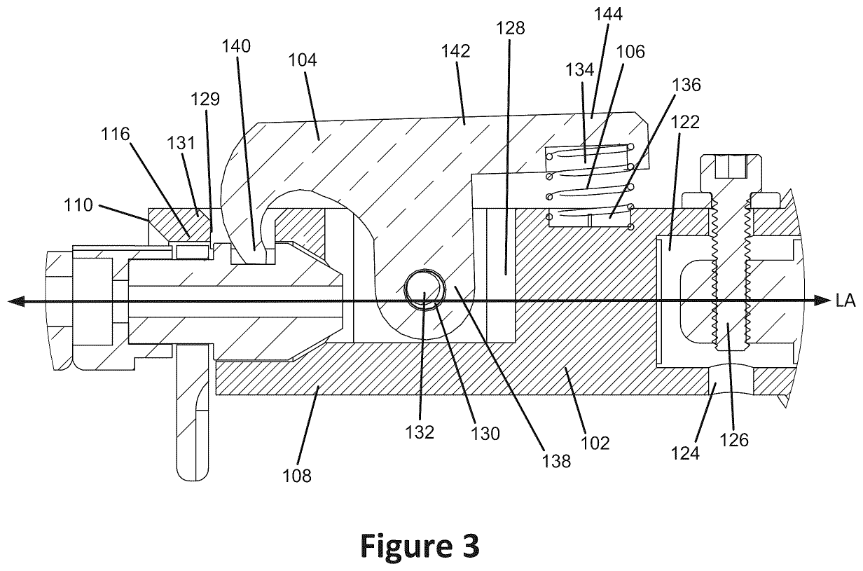

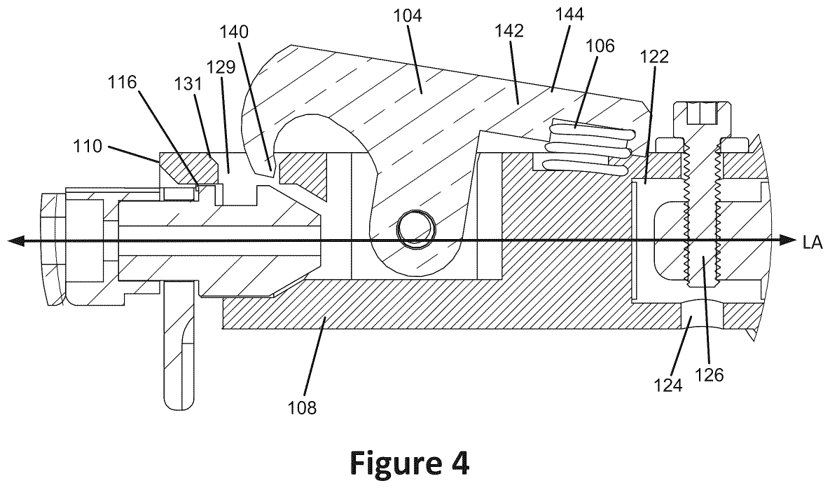

The proximal end 112 of the body 102 can define a second aperture 122 (as depicted in FIGS. 3-4), generally aligned with the longitudinal axis and shaped and sized to receive an end of an extension rod 60. In some embodiments, the second aperture 122 can be substantially cylindrical, with its axis generally aligned with the longitudinal axis of the body 102. Further, an extension rod pin aperture 124 can be defined in the body 102 to extend substantially orthogonal to the second aperture 122, enabling a pin 126 to be passed therethrough, thereby securing the extension rod 60 to the body 102.

The body 102 can further define a clip aperture 128, which can be a blind bore extending partially into the shaft 108 between the distal end 110 and the proximal end 112, substantially orthogonal to the longitudinal axis. In some embodiments, the clip aperture 128 can be a rectangular or elongated slot shaped and sized to enable a portion of the clip 104 to be positioned therein. In the context of the end effector device 100, a “blind bore” refers to a hole or cavity defined in the body 102 that does not extend all the way through to the opposite side. Instead, the clip aperture 128 terminates at a certain depth within the material of the body 102, creating a closed-end cavity.

The clip 104 can define a pivot portion 138, a latch grip 140, and a latch effector 142. In some embodiments, a pin aperture 130 can be defined in the body 102 to extend substantially orthogonal to the clip aperture 128, enabling a pin 132 to be passed therethrough, thereby securing the pivot portion 138 of the clip 104 to the body 102 in a manner that allows the clip 104 to transition between a stem engaging configuration (as depicted in FIG. 3) and a release configuration (as depicted in FIG. 4). The latch grip 140 can be configured to selectively grip a catch surface defined by the stem 52 of the microscope sample holder 50.

The latch effector 142, which can include one or more manipulation surfaces 144 can be configured to enable manual manipulation of the clip 104 between the stem engaging configuration and the release configuration. In embodiments, the latch effector 142 can be constructed to have a low profile with one or more filleted or chamfered corners 146, thereby enabling compatibility of the end effector device 100 with sample stages from a variety of manufacturers.

The spring 106, positioned between the clip 104 and the body 102, can be configured to bias the clip 104 to the stem engaging configuration. To aid in the retention of the spring 106 relative to the clip 104 and body 102, the clip 104 can define a spring retention cavity 134 configured to receive a first end of the spring 106, and the body 102 can define a spring retention cavity 136 configured to receive a second end of the spring 106. Alternative configurations of the spring retention cavities are also contemplated.

Collectively, the components of the end effector device 100 can be configured to facilitate the secure engagement and release of the sample holder stem within the scanning electron microscope.

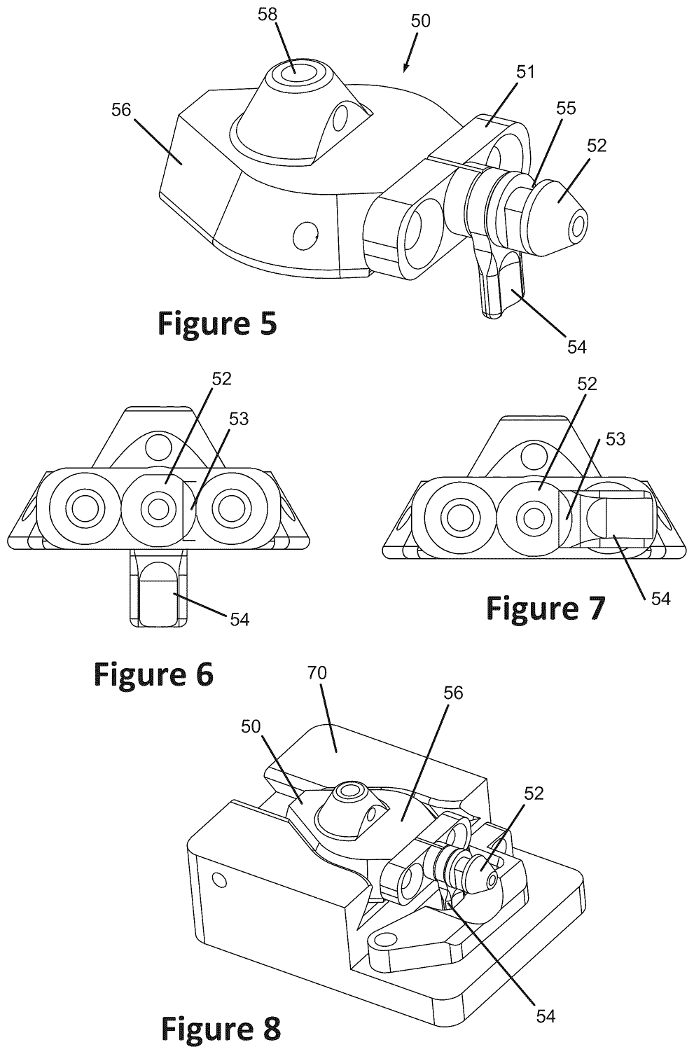

Referring to FIG. 5, a microscope sample holder 50, specifically an Atom Probe Topography (APT) style sample holder, is depicted. The microscope sample holder 50 includes a body 56, often referred to as a “puck,” which defines several features common to sample holders from various manufacturers. While the depicted puck design shows a single sample port 58 for loading a specimen for inspection under the SEM, different puck designs exist, featuring various hole sizes or even multiple holes to accommodate multiple samples simultaneously. Despite these variations, the general dimensions and purpose of key components such as the body 56, latch mechanism 51, stem 52, flag 54, and catch surface 55 remain similar across different designs, ensuring compatibility and functionality within SEM and other analytical instruments.

The latch mechanism 51 can include a stem 52 and a flag 54, which pivot around the stem 52 between a locked configuration, as shown in FIG. 6, and an unlocked configuration, as shown in FIG. 7. The stem 52, which is a substantially cylindrical projection, defines a catch surface 55 that the latch grip 140 of the clip 104 contacts. This catch surface can extend partially around the cylindrical projection, with at least a portion 53 of the stem 52, such as a 90° quadrant, free of the catch surface 55. This design allows the latch grip 140 to release its grip on the stem 52 when the clip 104 is rotated to the portion of the stem 52 free of the catch surface 55.

FIG. 8 shows the microscope sample holder 50 secured within a sample stage 70, with the flag 54 in the locked configuration, preventing the removal of the microscope sample holder 50 from the sample stage 70.

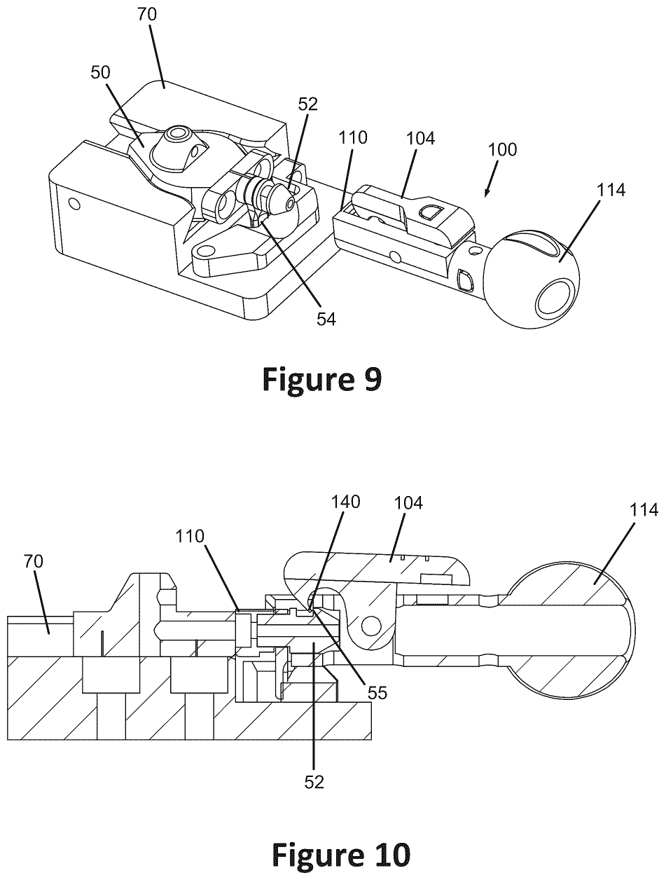

FIG. 9 illustrates the approach of the end effector device 100 to the microscope sample holder 50, with the distal end 110 oriented towards the stem 52, so that the stem 52 is at least partially received within the first aperture 116. As depicted in FIG. 10, with the end effector device 100 positioned such that the clip 104 is generally on top, the latch grip 140 of the clip 104 can make contact with the catch surface 55 defined by the stem 52, thereby securing the end effector device 100 to the microscope sample holder 50.

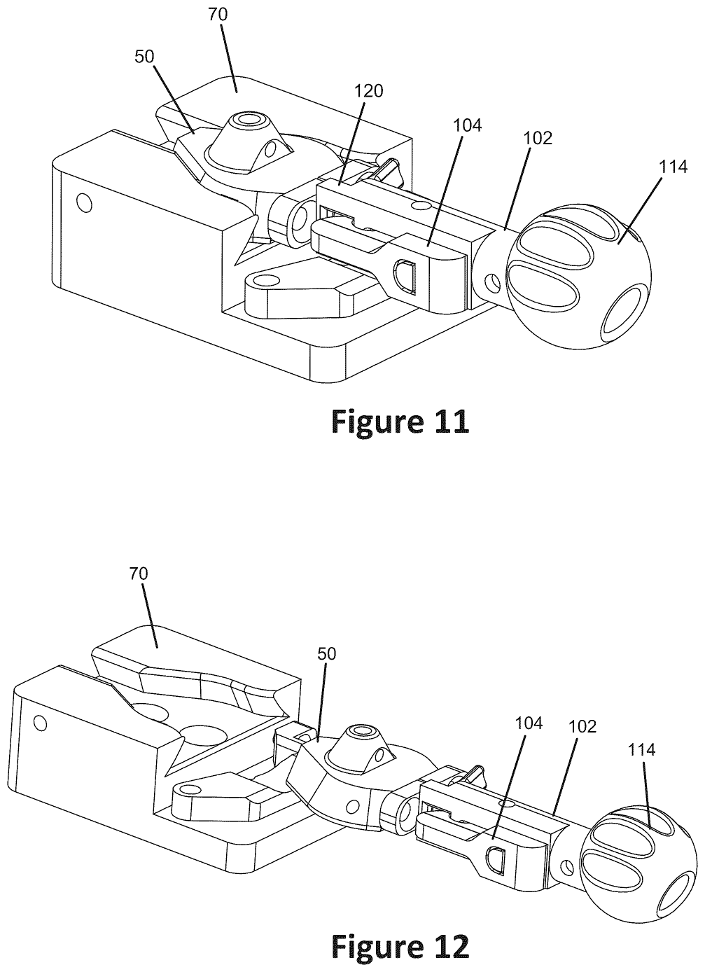

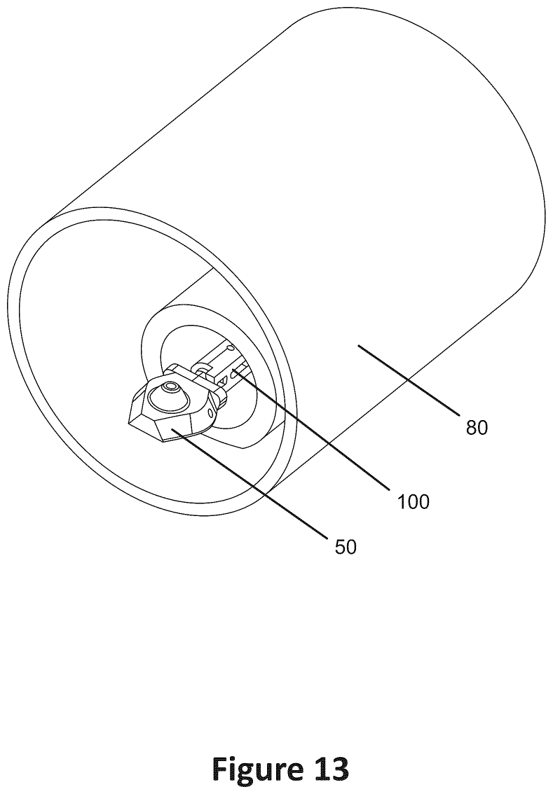

As depicted in FIG. 11, the end effector device 100 can be rotated approximately 90° counterclockwise, positioning the clip 104 on the side of the end effector device 100. This rotation causes the surface 118 to contact the flag 54, rotating the flag 54 from the locked configuration to the unlocked configuration. With the latch grip 140 still engaged with the catch surface 55, the microscope sample holder 50 can be removed from the sample stage 70, as shown in FIG. 12.

Repositioning the microscope sample holder 50 within the sample stage 70 can be accomplished by reversing the previously described steps. With additional reference to FIG. 13, the end effector device 100 is shown attached to the extension rod 60, which is, in turn, connected to the Specimen Shuttle Suitcase Device (SSSD) 80. The particular SSSD 80 depicted is manufactured by Quorum Technologies and is sometimes referred to as a “Quorum.” The SSSD 80 can be configured to store the sample in a controlled environment within the Quorum, and couple to an SEM 85 facilitating the transfer of the sample into the SEM 85 or other compatible instruments.

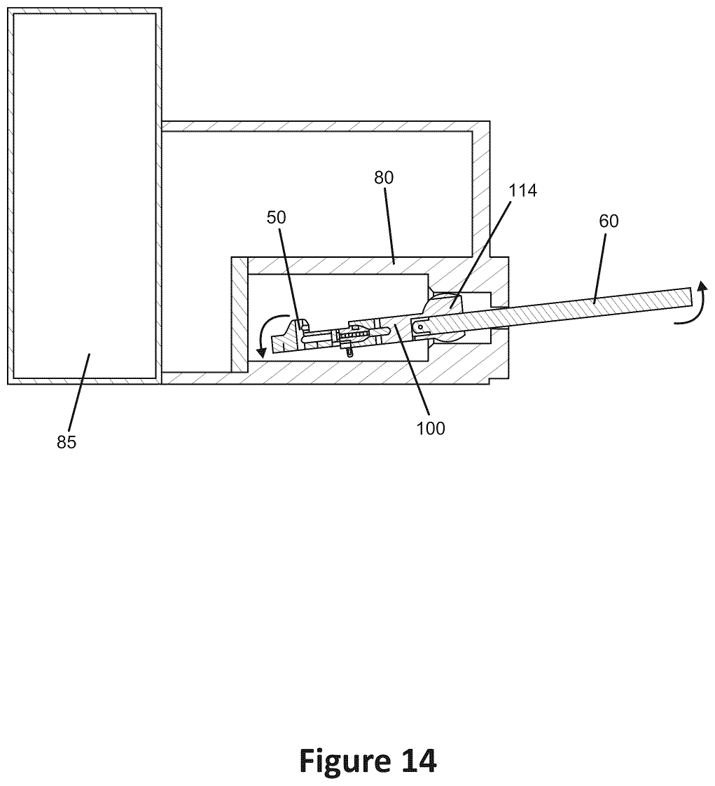

With the microscope sample holder 50 coupled to the end effector device 100, the user can grip the extension rod 60 to position the microscope sample holder 50 within the sample stage 70. As further depicted in FIG. 14, the bulbous portion 114 of the end effector device 100 is designed for contact with a portion of the SSSD 80. When withdrawing a sample, the SSSD 80 seals the microscope sample holder 50 in an airtight chamber. The SSSD 80 is then attached to a port on an SEM 85, and after pulling a vacuum, an airtight door opens, allowing the microscope sample holder 50 to be pushed into the SEM 85 and positioned on the sample stage 70. The extension rod 60 connected to the end effector device 100 can be manipulated around a fulcrum, aiding in maneuvering the sample holder. The bulbous portion 114 of the end effector device 100 can serve as an additional contact point inside the chamber, for example, guiding the sample downward and away from the walls, reducing the risk of collision.

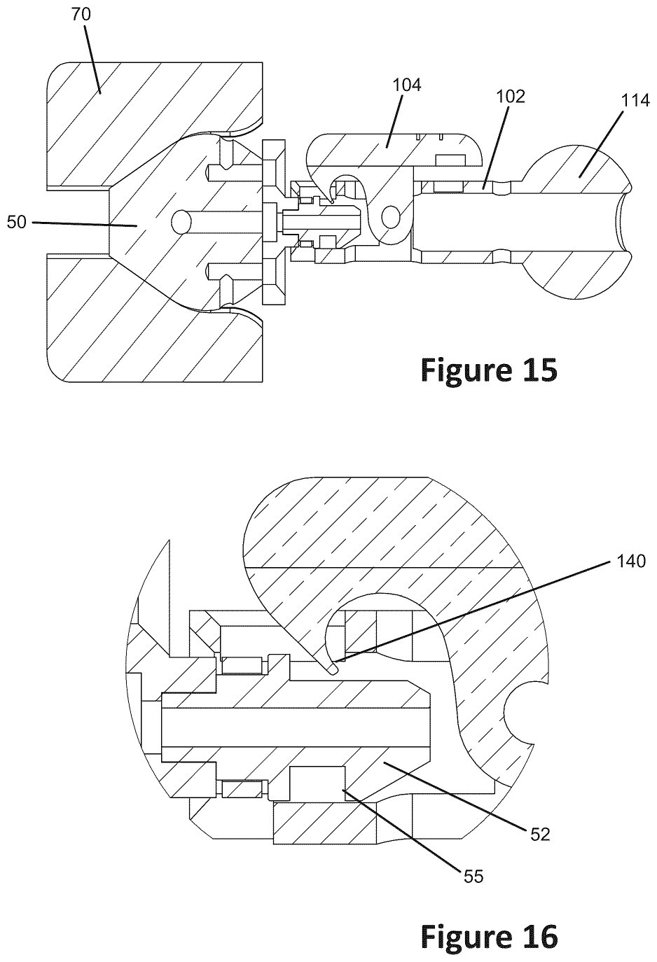

The end effector device 100 can then be rotated approximately 90° clockwise, causing the surface 120 to contact the flag 54. With the latch grip 140 still engaged with the catch surface 55 of the microscope sample holder 50, the end effector device 100 can be further rotated an additional 90° clockwise, as shown in FIG. 15. This rotation causes the latch grip 140 to slide along the catch surface 55 until it reaches the portion of the stem 52 free of the catch surface 55, at which point the physical grip of the end effector device 100 on the microscope sample holder 50 is released, as depicted in FIG. 16. The end effector device 100 can then be withdrawn, leaving the microscope sample holder 50 locked within the sample stage 70. Once the sample is secured, the airtight door is closed, and the SSSD 80 can be removed from the SEM 85.

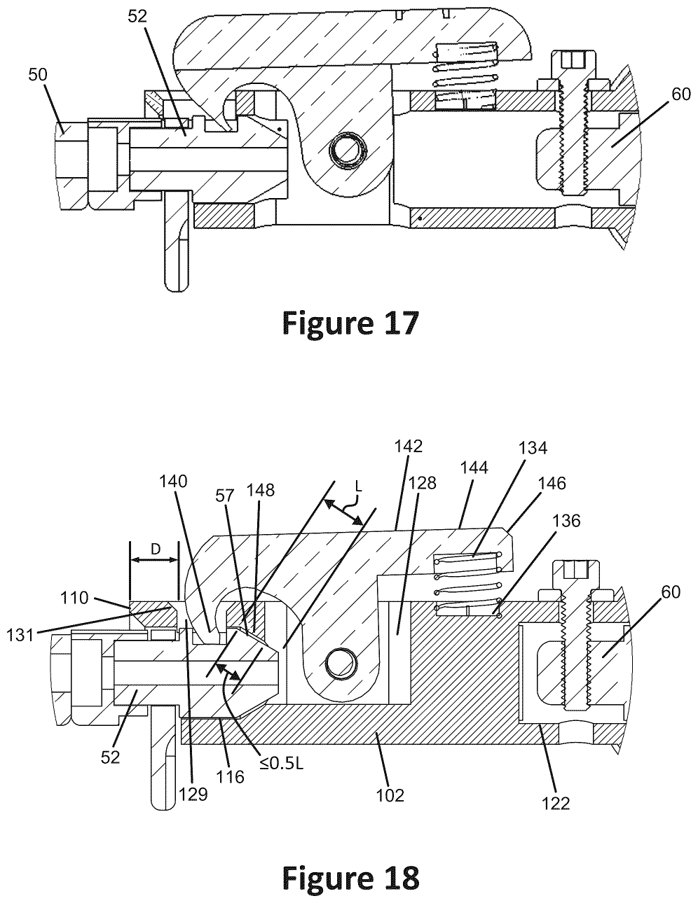

With additional reference to FIGS. 17-18, a direct comparison can be made between a flag-only end effector device 90 (depicted in FIG. 17) and the end effector device 100 of the present disclosure (depicted in FIG. 18), which represents an improvement over the flag-only end effector device 90. Notably, the end effector device 100 is configured to provide a more conforming fit to the stem 52 of the microscope sample holder 50. Specifically, the first aperture 116 can define an inner chamfer 148 that extends over at least half (e.g., 50%) of a length (L) of a corresponding chamfered surface 57 defined by the stem 52 of the microscope sample holder 50.

Additionally, the body can define a latch grip aperture 129, which is a blind bore oriented substantially parallel to the clip aperture 128, enabling the latch grip 140 to pass through and engage with the catch surface 55 of the stem 52. In conventional end effectors, the latch grip aperture 129 being positioned too close to the distal end 110 has been a common point of failure, leading to structural weakness and breakage. To address this issue, the end of the latch grip 140 can be reduced in size, allowing the latch grip aperture 129 to be repositioned further from the distal end 110, thereby providing more material at the distal end 110 for added strength and durability. For example, the first aperture 116 and the stem 52, the latch grip aperture 129 can be positioned at a distance (D) from the distal end 110 of the end effector device 100, which in some embodiments can be at least 1 mm. To reduce interference, the latch grip aperture 129 can include filleted or chamfered corners 131 positioned along an exterior surface of the body 102.

For improved structural rigidity, the end effector device 100 of the present disclosure features the clip aperture 128 as a blind bore, meaning it does not extend all the way through the material defining the body 102. This design improves the structural integrity of the body 102 by maintaining a solid exterior surface opposite the clip aperture 128, reducing the likelihood of stress fractures and other material degradations or failures during use.

The clip 104 defines a spring retention cavity 134 to receive one end of the spring 106, and the body 102 defines a spring retention cavity 136 to receive the other end. Additionally, the second aperture 122 can be positioned closer to the proximal end 112 than the spring retention cavity 136, ensuring no overlap between the second aperture 122 and the spring retention cavity 136 along the body 102. This arrangement reduces thin-walled areas of the body 102, which can help prevent stress fractures and other material degradations from initiating.

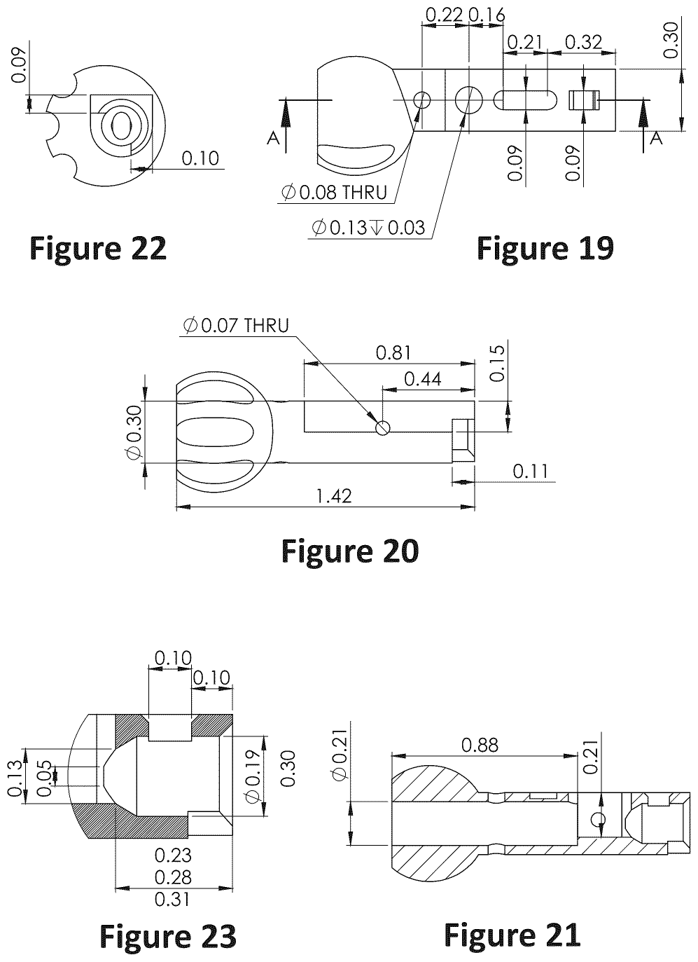

With reference to FIGS. 19-24, example dimensions of the body 102, along with the locations of the first aperture 116, second aperture 122, extension rod pin aperture 124, clip aperture 128, pin aperture 130, and latch grip aperture 129, as well as other features, are provided. These dimensions and angles represent one possible embodiment of the body 102 and should not be construed as limiting. For instance, certain dimensions may be altered based on the selected material and specific application requirements.

The body 102 of the end effector device 100 can be manufactured using a 3D printing process. The bulbous portion 114 can define the proximal end 112, which features a flat or planar surface configured to serve as the starting point for the 3D printing process. The printing process can then progress in layers from the proximal end 112 to the distal end 110, allowing for precise control over the geometry and dimensions of the body 102.

The ability to 3D print the end effector device 100 offers significant flexibility in material selection. This flexibility allows for the use of materials that can withstand extreme conditions, such as freezing or cryogenic temperatures, without degradation or warping. Additionally, materials with low thermal conductivity can be chosen to minimize thermal transfer between the end effector device 100 and the microscope sample holder 50. Materials that perform well under vacuum conditions, such as those that do not off-gas, are also suitable for this application. Furthermore, the material can be selected based on specific electrical and conductance properties required for the end effector device's operation. This versatility in material selection ensures that the end effector device 100 meets the demanding requirements of various scanning electron microscope applications.

In one embodiment, the end effector device 100 can be constructed of polyphenylsulfone (PPSU), which provides excellent mechanical properties and thermal stability. Additionally, the device can be constructed from a variety of other suitable materials depending on the specific application requirements. These materials can include polyetherketone (PEK), polyether ether ketone (PEEK), and other high-performance polymers such as polyimide (PI), polyetherimide (PEI), polyphenylene sulfide (PPS), and liquid crystal polymer (LCP). Selection among these materials can offer unique properties such as resistance to high temperatures, chemical resistance, and mechanical strength, making them ideal choices for the construction of the end effector device 100 in various operational environments.

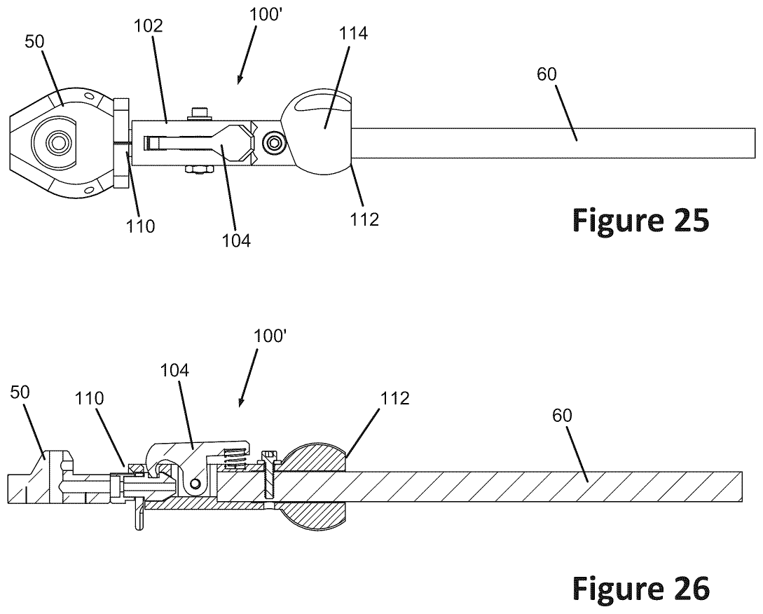

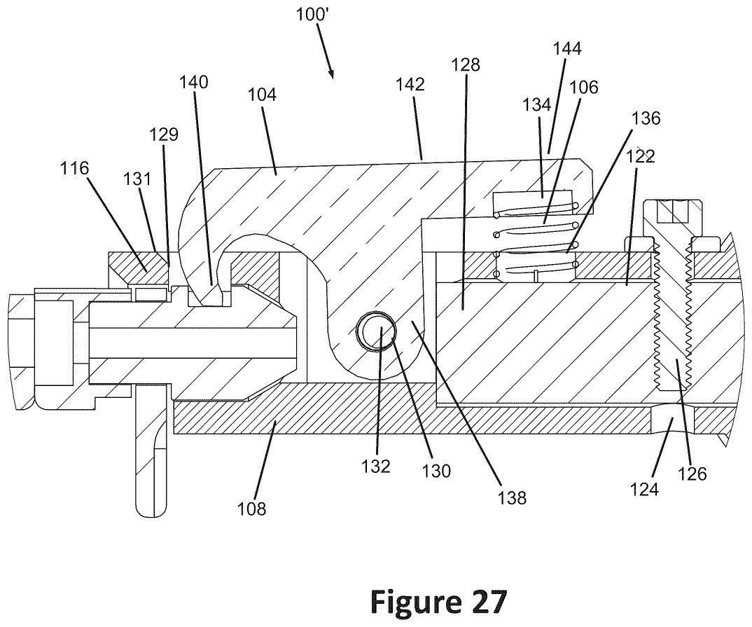

Referring to FIGS. 25-27, an alternative embodiment, end effector device 100′, is depicted. The purpose of the end effector device 100′ is to facilitate the loading and unloading of specimens in a scanning electron microscope. As depicted, the end effector device 100′ includes a body 102, a clip 104, and a spring 106.

The body 102 is defined by a shaft 108 extending along a longitudinal axis (LA) between a distal end 110 and a proximal end 112. A bulbous portion 114, generally having a knob-like or partially spherical shape, is formed near the proximal end 112, making the shaft 108 and the bulbous portion 114 a unitary, single-piece component.

The distal end 110 of the body 102 defines a first aperture 116, aligned with the longitudinal axis and sized to receive a stem 52 of a scanning electron microscope sample holder 50. The first aperture 116 can be a substantially cylindrical bore, with its axis aligned with the longitudinal axis of the body 102. The distal end 110 can also define surfaces 118, 120 configured to engage with a flag 54 on the microscope sample holder 50 as the end effector device 100′ is rotated either clockwise or counterclockwise.

The proximal end 112 of the body 102 defines a second aperture 122, aligned with the longitudinal axis and sized to receive an extension rod 60. The second aperture 122 can be substantially cylindrical, with its axis aligned with the longitudinal axis of the body 102. An extension rod pin aperture 124, defined in the body 102, extends orthogonally to the second aperture 122, enabling a pin 126 to secure the extension rod 60 to the body 102.

The body 102 further defines a clip aperture 128, a blind bore extending partially into the shaft 108 between the distal end 110 and the proximal end 112, orthogonal to the longitudinal axis. In some embodiments, the clip aperture 128 can be a rectangular or elongated slot sized to position a portion of the clip 104 within it. A “blind bore” refers to a hole or cavity in the body 102 that does not extend all the way through, terminating at a certain depth within the material.

The clip 104 defines a pivot portion 138, a latch grip 140, and a latch effector 142. A pin aperture 130 in the body 102 extends orthogonally to the clip aperture 128, enabling a pin 132 to secure the pivot portion 138 of the clip 104 to the body 102, allowing the clip 104 to transition between a stem engaging configuration and a release configuration. The latch grip 140 is configured to selectively grip a catch surface on the stem 52 of the microscope sample holder 50.

The latch effector 142, which includes one or more manipulation surfaces 144, enables manual manipulation of the clip 104 between the stem engaging and release configurations. The latch effector 142 can have a low profile with filleted or chamfered corners 146, enabling compatibility with various SSSDs.

In this embodiment, the spring retention cavity 136 intersects with the second aperture 122, allowing one end of the spring 106 to rest directly against the extension rod 60. The spring 106, positioned between the clip 104 and the body 102, biases the clip 104 to the stem engaging configuration. The clip 104 defines a spring retention cavity 134 to receive one end of the spring 106, and the body 102 defines a spring retention cavity 136 to receive the other end. Alternative configurations of the spring retention cavities are also contemplated. Collectively, the components of the end effector device 100′ facilitate the secure engagement and release of the sample holder stem within the scanning electron microscope.

The end effector devices 100, 100′ may be fabricated using various 3D printing methods, including but not limited to material extrusion, vat polymerization (resin printing), or powder bed fusion. Each of these methods offers distinct advantages and considerations depending on the specific application requirements and material properties.

In embodiments where the end effector devices 100, 100′ are fabricated using material extrusion, the process typically requires the presence of a flat surface, such as the flat proximal end 112 on the bulbous portion 114, to optimize the printing process. Material extrusion, which involves extruding melted material layer by layer to build the part, inherently requires the construction of support structures to prevent the collapse of layers during printing. In this context, the end effector device 100 may be oriented vertically during the printing process to minimize the number of internal supports required, particularly within features such as the clip aperture 128, latch grip aperture 129, and similar cavities. This vertical orientation reduces the complexity associated with the removal of internal supports, which can be challenging and may risk damaging the structural integrity or surface finish of the printed part.

Alternatively, in embodiments where the end effector devices 100, 100′ are produced using powder bed fusion, the process benefits from the inherent support provided by the unfused powder medium. Powder bed fusion involves selectively fusing powder particles using a laser or another heat source, and since the unfused powder acts as a support, this method does not require additional support structures. The absence of a need for a flat surface for the initial printing layer and the flexibility of part orientation during printing improve the overall efficiency and material utilization in the manufacturing process.

In other embodiments, the end effector devices 100, 100′ may be fabricated using vat polymerization (resin printing). This method uses a light source to cure liquid resin layer by layer to form the part, which is capable of producing high-detail parts with minimal and minimally disruptive supports. Although vat polymerization typically benefits from initiating the printing process on a flat surface, such as the flat proximal end 112, the high-resolution capability of resin printing allows for more intricate designs to be printed with tiny supports that can be easily removed without compromising the surface finish or functionality of the part.

The choice of 3D printing method for fabricating the end effector devices 100, 100′ will depend on the specific material properties required, the environmental conditions in which the device will operate, and the desired level of detail and structural integrity.

Having described the preferred aspects and implementations of the present disclosure, modifications and equivalents of the disclosed concepts may readily occur to one skilled in the art. However, it is intended that such modifications and equivalents be included within the scope of the claims which are appended hereto.

Various advantages and novel features of the present disclosure are described herein and will become further readily apparent to those skilled in this art from the following detailed description. In the preceding and following descriptions the preferred embodiment of the disclosure have been shown and described by way of illustration of the best mode contemplated for carrying out the disclosure. As will be realized, the disclosure is capable of modification in various respects without departing from the disclosure. Accordingly, the drawings and description of the preferred embodiment set forth hereafter are to be regarded as illustrative in nature, and not as restrictive.

What is claimed is:

1. An end effector device for use with a scanning electron microscope, comprising:
a body defining a shaft extending along a longitudinal axis between a distal end and a proximal end, the proximal end including a bulbous portion, the distal end defining a first aperture aligned with the longitudinal axis and configured to receive a stem of a scanning electron microscope sample holder, and the proximal end defining a second aperture aligned with the longitudinal axis and configured to receive an end of an extension rod, wherein the body further defines a clip aperture defined as a blind bore extending partially into the shaft between the distal end and the proximal end substantially orthogonal to the longitudinal axis;
a clip positioned within the clip aperture and held in position with a pin traversing through a pin aperture extending through the body, enabling the clip to transition between a stem engaging configuration and a release configuration; and
a spring positioned between the clip and the body to bias the clip to the stem engaging configuration.

2. The end effector device of claim 1, wherein the body is 3D printed through a 3D printing process, and wherein the bulbous portion defines a planar portion of the proximal end of the body configured to serve as a starting point for the 3D printing process.

3. The end effector device of claim 2, wherein the 3D printing process progresses in layers between the planar portion of the proximal end and the distal end.

4. The end effector device of claim 2, wherein the body is constructed of polyphenylsulfone (PPSU).

5. The end effector device of claim 1, wherein the first aperture defines an inner chamfer including a surface configured to extend over at least 50% of a corresponding chamfered surface of the stem of the scanning electron microscope sample holder.

6. The end effector device of claim 1, wherein the clip defines a latch grip and the body further defines a latch grip aperture oriented substantially parallel to the clip aperture, enabling the latch grip to grip the stem of the scanning electron microscope sample holder positioned within the first aperture, wherein the latch grip aperture is positioned at a distance of at least 1 mm from the distal end.

7. The end effector device of claim 6, wherein the latch grip aperture includes at least one of filleted or chamfered corners positioned along an exterior surface of the body.

8. The end effector device of claim 7, wherein the clip further defines a latch effector presenting a manipulation surface featuring at least one of chamfered or filleted corners, enabling compatibility of the end effector device with a variety of scanning electron microscope sample stage configurations.

9. An end effector device for use with a scanning electron microscope, comprising:
a body defining a shaft extending along a longitudinal axis between a distal end and a proximal end, the proximal end including a bulbous portion, the distal end defining a first aperture aligned with the longitudinal axis and configured to receive a stem of a scanning electron microscope sample holder, and the proximal end defining a second aperture aligned with the longitudinal axis and configured to receive an end of an extension rod, wherein the body further defines a clip aperture defined as a blind bore extending partially into the shaft between the distal end and the proximal end substantially orthogonal to the longitudinal axis;
a clip positioned within the clip aperture and held in position with a pin traversing through a pin aperture extending through the body, enabling the clip to transition between a stem engaging configuration and a release configuration;
a spring positioned between the clip and the body to bias the clip to the stem engaging configuration; and
wherein the first aperture defines an inner chamfer including a surface configured to extend over at least 50% of a corresponding chamfered surface of the stem of the scanning electron microscope sample holder.

10. The end effector device of claim 9, wherein the body is 3D printed through a 3D printing process, and wherein the bulbous portion defines a planar portion of the proximal end of the body configured to serve as a starting point for the 3D printing process.

11. The end effector device of claim 10, wherein the 3D printing process progresses in layers between the planar portion of the proximal end and the distal end.

12. The end effector device of claim 10, wherein the body is constructed of polyphenylsulfone (PPSU).

13. The end effector device of claim 9, wherein the clip defines a latch grip and the body further defines a latch grip aperture oriented substantially parallel to the clip aperture, enabling the latch grip to grip the stem of the scanning electron microscope sample holder positioned within the first aperture, wherein the latch grip aperture is positioned at a distance of at least 1 mm from the distal end.

14. The end effector device of claim 13, wherein the latch grip aperture includes at least one of filleted or chamfered corners positioned along an exterior surface of the body.

15. The end effector device of claim 14, wherein the clip further defines a latch effector presenting a manipulation surface featuring at least one of chamfered or filleted corners, enabling compatibility of the end effector device with a variety of scanning electron microscope sample stage configurations.

16. An end effector device for use with a scanning electron microscope, comprising:
a body defining a shaft extending along a longitudinal axis between a distal end and a proximal end, the proximal end including a bulbous portion, the distal end defining a first aperture aligned with the longitudinal axis and configured to receive a stem of a scanning electron microscope sample holder, and the proximal end defining a second aperture aligned with the longitudinal axis and configured to receive an end of an extension rod, wherein the body further defines a clip aperture defined as a blind bore extending partially into the shaft between the distal end and the proximal end substantially orthogonal to the longitudinal axis;
a clip positioned within the clip aperture and held in position with a pin traversing through a pin aperture extending through the body, enabling the clip to transition between a stem engaging configuration and a release configuration;
a spring positioned between the clip and the body to bias the clip to the stem engaging configuration; and
wherein the clip defines a latch grip and the body further defines a latch grip aperture oriented substantially parallel to the clip aperture, enabling the latch grip to grip the stem of the scanning electron microscope sample holder positioned within the first aperture, wherein the latch grip aperture is positioned at a distance of at least 1 mm from the distal end.

17. The end effector device of claim 16, wherein the latch grip aperture includes at least one of filleted or chamfered corners positioned along an exterior surface of the body.

18. The end effector device of claim 16, wherein the clip further defines a latch effector presenting a manipulation surface featuring at least one of filleted or chamfered corners, enabling compatibility of the end effector device with a variety of scanning electron microscope sample stage configurations.

19. The end effector device of claim 16, wherein the body is 3D printed through a 3D printing process, and wherein the bulbous portion defines a planar portion of the proximal end of the body configured to serve as a starting point for the 3D printing process.

20. The end effector device of claim 19, wherein the body is constructed of polyphenylsulfone (PPSU).

21. The end effector device of claim 16, wherein the first aperture defines an inner chamfer including a surface configured to extend over at least 50% of a corresponding chamfered surface of the stem of the scanning electron microscope sample holder.

22. A method for manipulating a microscope sample holder within a scanning electron microscope using an end effector device, the method comprising:
positioning a distal end of the end effector device near a stem of the microscope sample holder such that the stem is at least partially received within a first aperture of the end effector device;
engaging a latch grip of a clip within the end effector device with a catch surface defined by the stem of the microscope sample holder, thereby securing the end effector device to the microscope sample holder;
rotating the end effector device approximately 90 degrees in a counterclockwise direction, causing a surface of the end effector device to contact a flag on the microscope sample holder, pivoting the flag from a locked configuration to an unlocked configuration; and
withdrawing the microscope sample holder from a sample stage of the scanning electron microscope while maintaining the latch grip engaged with the catch surface of the stem.

23. The method of claim 22, further comprising positioning the microscope sample holder within the sample stage to ensure that the stem is received within the first aperture of the end effector device and the latch grip engages with the catch surface of the stem.

24. The method of claim 23, further comprising rotating the end effector device in a clockwise direction, causing the surface of the end effector device to contact the flag, pivoting the flag from the unlocked configuration to the locked configuration.

25. The method of claim 24, further comprising additionally rotating the end effector device an additional 90 degrees in the clockwise direction, causing the latch grip to slide along the catch surface of the stem until it reaches a portion of the stem free of the catch surface, thereby releasing a physical grip of the end effector device on the microscope sample holder.

26. The method of claim 25, further comprising withdrawing the end effector device, leaving the microscope sample holder locked within the sample stage.
